(19) United States
(12) Patent Application Publication
(10) Pub. No.: US 2008/0223527 A1
(43) Pub. Date: Sep. 18, 2008

(54) Method For Patterning Reel-To-Reel Strip In Automatic Manufacturing Process

(76) Inventors: Chin-Fu Chung, Taoyuan Hsien (TW); Chiu-Tang Chen, Hsinchu Hsien (TW)

Correspondence Address: LIN & ASSOCIATES INTELLECTUAL PROPERTY, INC., P.O. BOX 2339, SARATOGA, CA, 95070-0339, US

(21) Appl. No.: 11/685,742

(22) Filed: Mar. 13, 2007

(51) Int. Cl. H05K 3/04

(52) U.S. Cl. 156/545; 438/460; 438/463

(57) ABSTRACT

In a method for patterning a reel-to-reel strip in an automatic manufacturing process, a reel-to-reel strip is stuck onto a support plate having a low-tack adhesive. A laser beam is used to pattern the reel-to-reel strip. Carbon residues and/or cut pieces generated during a process of patterning the reel-to-reel strip are stuck on the support plate having the low-tack adhesive. Therefore, the carbon residues and/or the cut pieces will not fall down to other parts of the reel-to-reel strips during the automatic manufacturing process. Thus, it does not need to remove the carbon residues and/or the cut pieces from the reel-to-reel strips.

### BACKGROUND OF THE INVENTION

1. Field of the Invention

The present invention relates to a method for patterning a reel-to-reel strip in an automatic manufacturing process, and in particular to a patterning method which can prevent carbon residues and/or cut pieces from falling down.

2. The Prior Arts

A flexible printed circuit board is a substrate to mechanically support and electrically connect electronic components. A copper foil is laminated on one side or both sides of a resin substrate, and patterned by image transfer, thereby forming circuits. The circuits then electrically connect with chips or other electronic components. Chips or other electronic components then electrically connect with each other using the circuits.

In the process of the patterning, a hole, such as a blind via, a through via, or an alignment hole, is formed by mechanical drilling, laser drilling, photo via forming, plasma etching or chemical etching, etc.

The laser drilling uses CO₂ mixed with other gas, such as N₂, He, and CO, to emit pulsed infrared laser beam having a wavelength between 9,300 nm˜10,600 nm under increased power and maintained discharging time. However, during the laser drilling process, the resin substrate is prone to be carbonized due to the high temperature, so that carbon residues or debris will form on the surface of the flexible board or fall down through the holes.

A cleaning process removes the carbon residues and debris after repeated given periods. However, it is not feasible to remove the carbon residues and debris during the continuous automatic manufacturing process for the flexible board. Thus, Taiwan Patent Issue No. 407530, “Improved Cleaning Device for Flexible Board”, discloses a device to remove the carbon residues and debris. However, the improved cleaning device for flexible board is still unable to satisfactorily remove the carbon residues and debris completely.

In order to completely solve the problem of the carbon residues and debris, Taiwan Patent No. I249977, “Method for Manufacturing High-density Flexible Circuit Board”, uses regular etching or plasma etching to form holes. The manufacturing method does not generate high heat during the hole forming process, so that it does not generate the carbon residues and debris during the etching process. Thus, the method solves the problem of carbon residues and debris.

However, the plasma etching can only etch the resin substrate but not the copper foil. Therefore, it needs other etching processes such as chemical etching used together with the plasma etching to etch the copper foil. It is unlike the laser drilling process, which directly drills predetermined holes through the copper foil and the resin substrate, and thus make the manufacturing process more complicate.

### SUMMARY OF THE INVENTION

A primary objective of the present invention is to provide a method for patterning a reel-to-reel strip in an automatic manufacturing process, which sticks carbon residues and/or cut pieces produced by laser drilling and prevents them from falling down onto and contaminating other reel-to-reel strips.

Based on the above objective, the method for patterning a reel-to-reel strip in an automatic manufacturing process in accordance with the present invention is attaching the reel-to-reel strip to a support plate having a low-tack adhesive, so that the carbon residues and the cut pieces are stuck on the support plate with the low-tack adhesive. Therefore, the carbon residues and cut pieces will not fall down to other reel-to-reel strips, and it does not need to clean the carbon residues and cut pieces.

### BRIEF DESCRIPTION OF THE DRAWINGS

The present invention will be apparent to those skilled in the art by reading the following detailed description of preferred embodiments thereof, with reference to the attached drawings, in which:

FIGS. 1A-1B are schematic views showing a reel-to-reel strip and a support plate having a low-tack adhesive used in a method for patterning a reel-to-reel strip in an automatic manufacturing process in accordance with the present invention;

FIGS. 2A-2B are schematic views showing a method for patterning a reel-to-reel strip in an automatic manufacturing process in accordance with a first embodiment of the present invention; and

FIG. 3 is a schematic view showing a method for patterning a reel-to-reel strip in an automatic manufacturing process in accordance with a second embodiment of the present invention.

### DETAILED DESCRIPTION OF THE PREFERRED EMBODIMENT

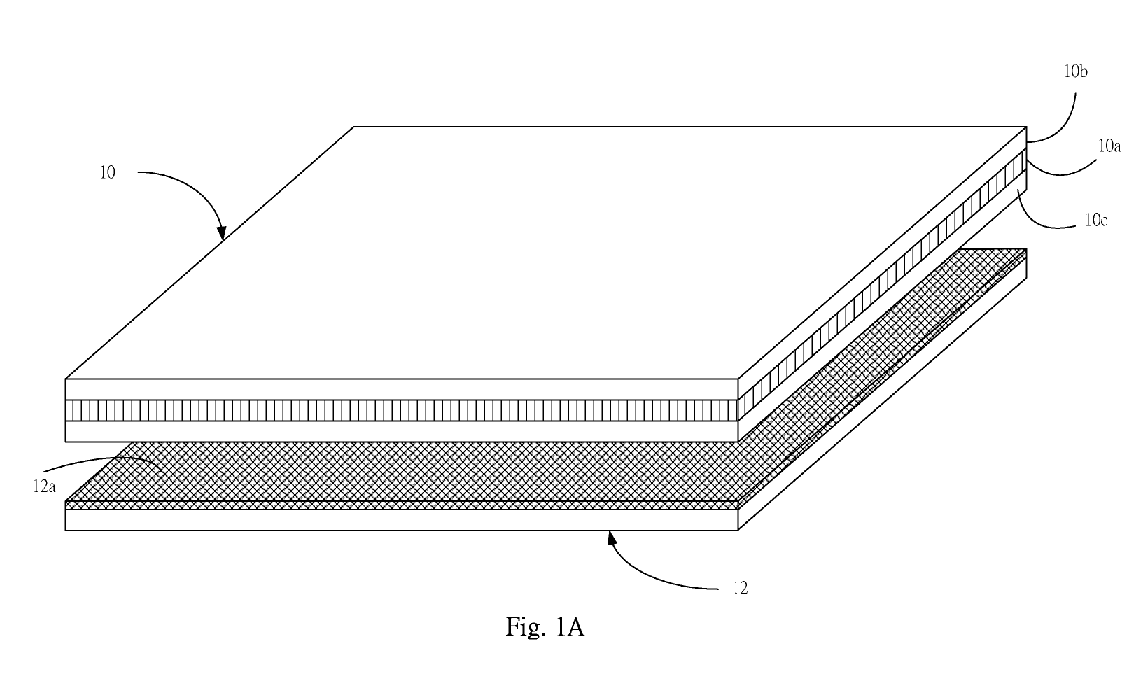

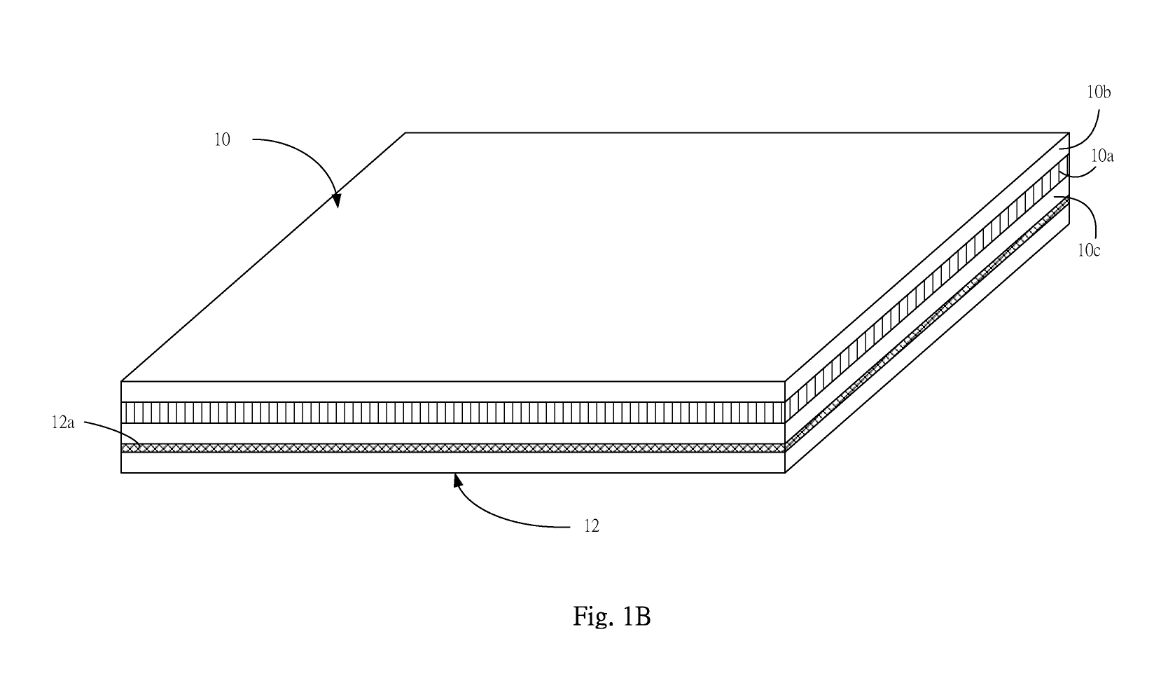

Referring to FIG. 1A, a reel-to-reel strip 10 and a support plate 12 (PET may be used) having a low-tack adhesive 12a are provided. The reel-to-reel strip 10 may be one of a cover layer, a reinforcement plate and a flexible circuit board. When the reel-to-reel strip 10 is the flexible circuit board, a copper foil 10b or 10c is laminated to one side of a resin substrate 10a (PI may be used) or copper foils 10b and 10c are laminated to both sides of the resin substrate 10a respectively.

Referring to FIG. 1B, the reel-to-reel strip 10 is adhered to the support plate 12 having the low-tack adhesive 12a. After attachment, a laser beam is used to pattern the reel-to-reel strip 10. Carbon residues and/or cut pieces generated by laser beam patterning the reel-to-reel strip 10 are stuck on the support plate 12 having the low-tack adhesive 12a so that the carbon residues and cut pieces will not fall down to contaminate other products or semi-finished products. The following descriptions are embodiments of drilling hole and patterning.

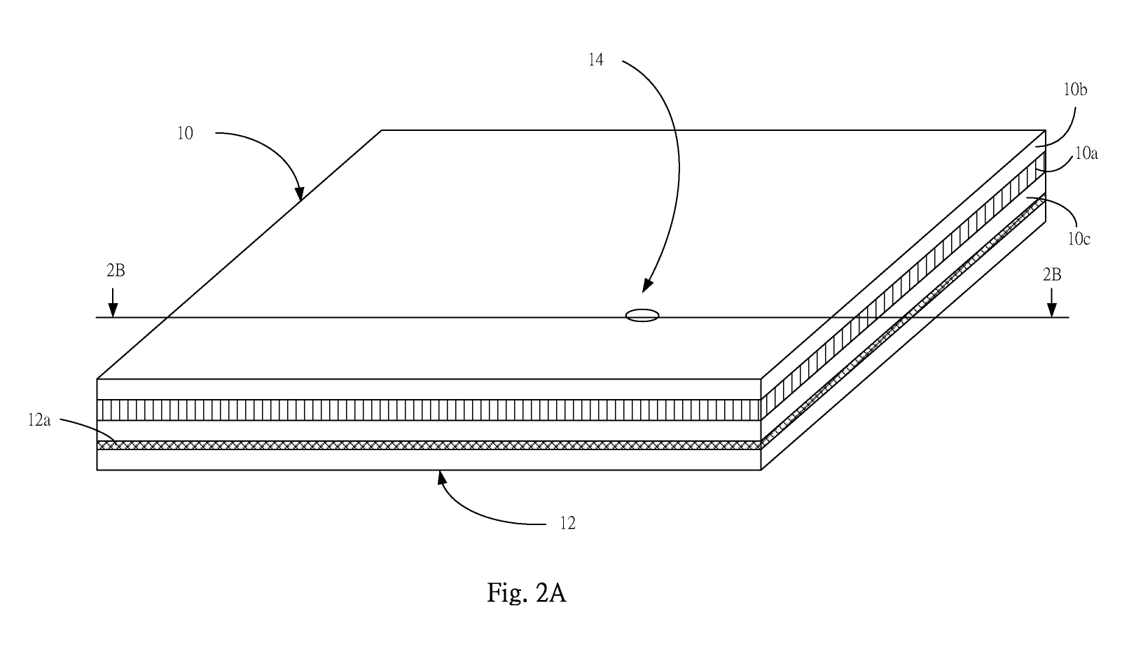

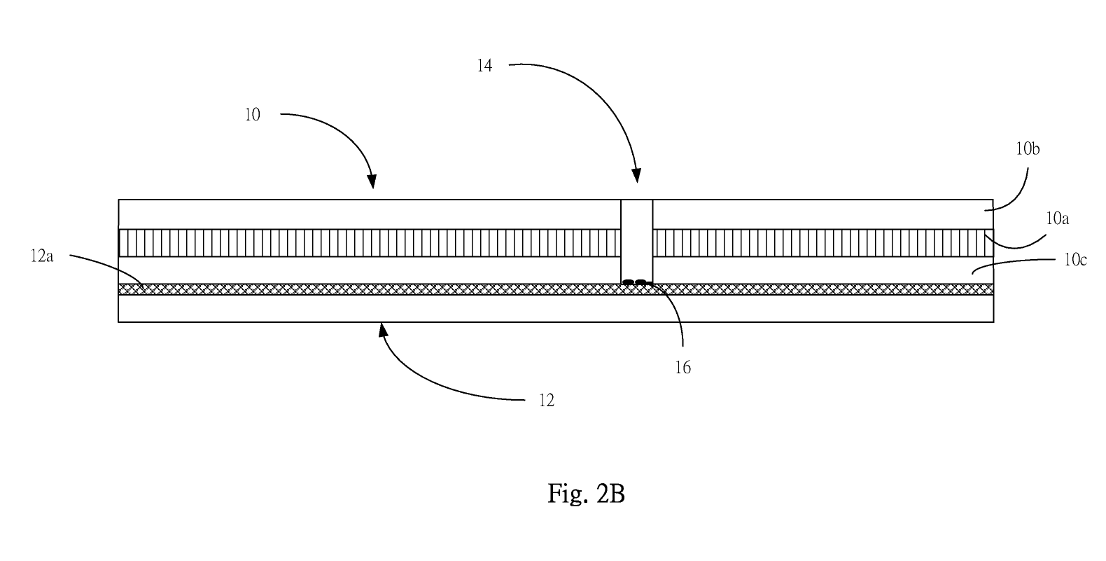

FIGS. 2A-2B show a method for patterning a reel-to-reel strip in an automatic manufacturing process in accordance with a first embodiment of the present invention. FIG. 2B is a cross-sectional view taken along a line 2B-2B in FIG. 2A. The laser beam drills a hole 14 at a predetermined position on the reel-to-reel strip 10 as shown in FIGS. 2A and 2B. The carbon residues 16 adheres to the support plate 12 with the low-tack adhesive 12a as shown in FIG. 2B. The hole 14 may be a through hole or an alignment hole. If the hole 14 is an alignment hole, precision of alignment is enhanced due to blackness of the carbon residues 16 that enhance the color contrast between the hole 14 and other parts.

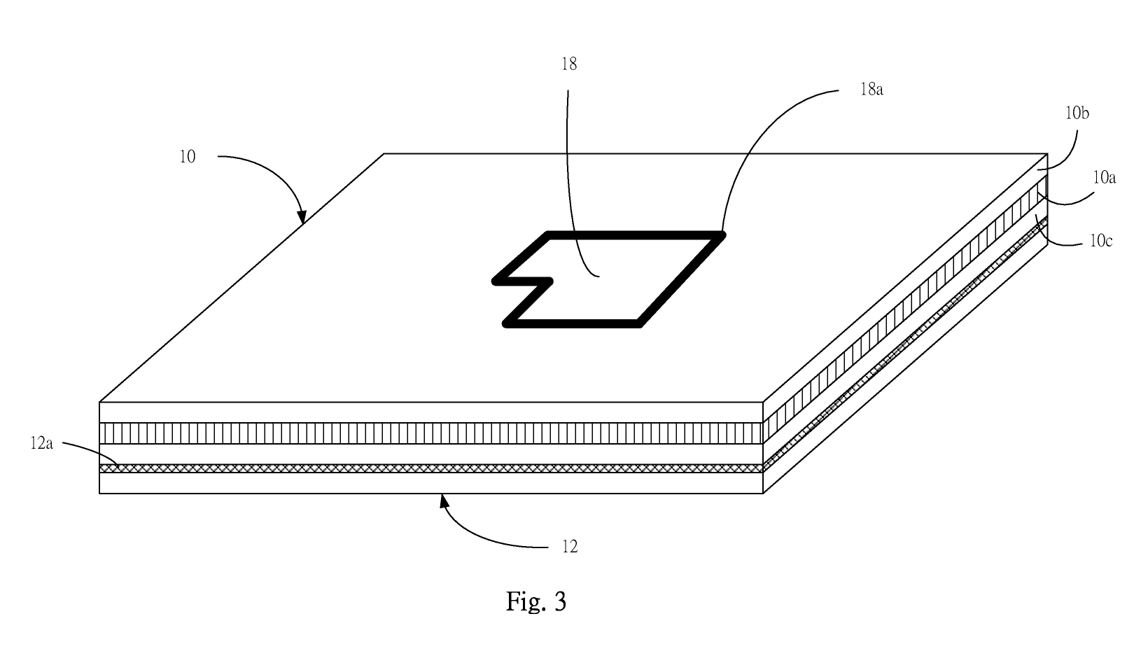

FIG. 3 shows a method for patterning a reel-to-reel strip in an automatic manufacturing process in accordance with a second embodiment of the present invention. The laser beam continuously cuts the reel-to-reel strip 10 along a line 18a, and thus cut a piece 18 from the reel-to-reel strip 10 as shown in FIG. 3. In addition to the carbon residues generated during cutting the line 18a, the cut piece 18 also adheres to the support plate 12 having the low-tack adhesive 12a.

If the reel-to-reel strips 10 are the reinforcement plates or other plates, the method according to the present invention uses the laser beam to cut pieces from the reel-to-reel strip. It does not need to design and manufacture molds, so that the products can be delivered to the customers rapidly. The cost of cutting pieces using the method according to the present invention may be higher than using the molds, but it is capable of manufacturing samples rapidly and easily for the market testing. It prevents discarding or amending the molds in case the products are not accepted in the market.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A method for patterning a reel-to-reel strip in an automatic manufacturing process, comprising the steps of:
providing a reel-to-reel strip;
providing a support plate having a low-tack adhesive;
sticking the reel-to-reel strip onto the support plate having the low-tack adhesive; and
patterning the reel-to-reel strip by using a laser beam;
wherein a carbon residue and/or a cut piece generated during the process of patterning the reel-to-reel strip are stuck on the support plate with the low-tack adhesive.

2. The method as claimed in claim 1, wherein the reel-to-reel strip is one of a cover layer, a reinforcement plate, and a flexible circuit board having a copper foil laminated on one side or both sides of a resin substrate.

3. The method as claimed in claim 1, wherein patterning the reel-to-reel strip is one of drilling a hole on the reel-to-reel strip and cutting a piece from the reel-to-reel strip by using the laser beam.

4. The method as claimed in claim 3, wherein the hole is one of a through hole and an alignment hole.
